(19) United States
(12) Patent Application Publication
(10) Pub. No.: US 2017/0294887 A1
(43) Pub. Date: Oct. 12, 2017

(54) SEMICONDUCTOR DEVICE

(71) Applicant: Mitsubishi Electric Corporation, Tokyo (JP)

(72) Inventors: Yoshitaka KAMO, Tokyo (JP); Yoshitsugu YAMAMOTO, Tokyo (JP)

(73) Assignee: Mitsubishi Electric Corporation, Tokyo (JP)

(21) Appl. No.: 15/361,220

(22) Filed: Nov. 25, 2016

(30) Foreign Application Priority Data
Apr. 7, 2016 (JP) 2016-077526

(51) Int. Cl. H03F 3/60; H01L 23/66; H03F 3/193; H01L 27/06

(52) U.S. Cl. CPC H03F 3/604; H01L 27/0605; H01L 23/66; H03F 3/193; H03F 2200/408

(57) ABSTRACT

A semiconductor device includes: a semiconductor substrate whose contour is a pentagon; a front-stage amplifier formed relatively near a vertex of the pentagon of the semiconductor substrate; and a rear-stage amplifier formed relatively near a side opposed to the vertex of the semiconductor substrate and amplifying an output from the front-stage amplifier.

### BACKGROUND OF THE INVENTION

### Field

The present invention relates to a semiconductor device including a front-stage amplifier and a rear-stage amplifier formed on a semiconductor substrate.

### Background

Conventional monolithic microwave integrated circuits (MMICs) are formed on rectangular semiconductor substrates (see, for example, Koh Kanaya et al., “A Ku-band 20 W GaN-MMIC Amplifier with Built-in Linearizer”, 2014 IEEE).

An ordinary MMIC is constituted of amplifiers in a plurality of stages, and the number of FETs in a rear stage is larger than the number of FETs in a front stage. Empty spaces therefore exist on the periphery of the front stage and it is difficult to reduce the chip cost by reducing the chip area.

### SUMMARY

In view of the above-described problems, an object of the present invention is to provide a semiconductor device capable of reducing the chip area to reduce the chip cost.

According to the present invention, a semiconductor device includes: a semiconductor substrate whose contour is a pentagon; a front-stage amplifier formed relatively near a vertex of the pentagon of the semiconductor substrate; and a rear-stage amplifier formed relatively near a side opposed to the vertex of the semiconductor substrate and amplifying an output from the front-stage amplifier.

In the present invention, the semiconductor substrate having a pentagonal contour is used, the front-stage amplifier is formed relatively near one vertex, and the rear-stage amplifier is formed relatively near the side opposed to the vertex. Empty spaces on the front stage side can thereby be reduced in comparison with the case of the conventional rectangular semiconductor substrate. The chip area can thus be reduced to reduce the chip cost.

Other and further objects, features and advantages of the invention will appear more fully from the following description.

### BRIEF DESCRIPTION OF DRAWINGS

FIG. 1 is a plan view of a semiconductor device according to a first embodiment of the present invention.

FIG. 2 is a plan view showing a state where pentagonal semiconductor substrates are arranged on a wafer.

FIG. 3 is a plan view showing a state where conventional rectangular semiconductor substrates are arranged on a wafer.

FIG. 4 is a plan view showing a semiconductor device according to a second embodiment of the present invention.

FIG. 5 is a plan view showing a state where semiconductor substrates in isosceles triangle form are arranged on a wafer.

FIG. 6 is a plan view showing a semiconductor device according to a third embodiment of the present invention.

FIG. 7 is a plan view showing a state where semiconductor substrates in isosceles trapezoid form are arranged on a wafer.

### DESCRIPTION OF EMBODIMENTS

A semiconductor device according to the embodiments of the present invention will be described with reference to the drawings. The same components will be denoted by the same symbols, and the repeated description thereof may be omitted.

### First Embodiment

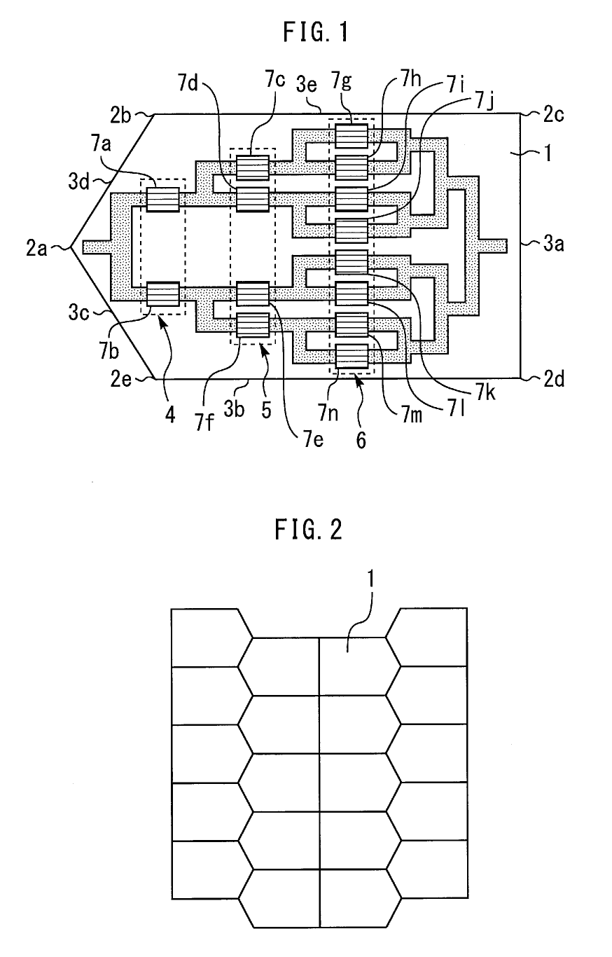

FIG. 1 is a plan view of a semiconductor device according to a first embodiment of the present invention. The contour of the semiconductor substrate 1 is a pentagon having five vertices 2a to 2e and five sides 3a to 3e. The side 3a is opposed to the vertex 2a. The vertex 2a is placed on a perpendicular to the side 3a passing through the middle point of the side 3a. The sides 3b and 3e are parallel to each other and equal in length to each other. The sides 3c and 3d are equal in length to each other.

An MMIC of a three-stage configuration is formed on the semiconductor substrate 1. An amplifier 5 in the second stage amplifies outputs from an amplifier 4 in the first stage, and an amplifier 6 in the final stage amplifies outputs from the amplifier 5 in the second stage. The amplifier 4 in the first stage has two FETs 7a and 7b. The amplifier 5 in the second stage has four FETs 7c to 7f. The amplifier 6 in the final stage has eight FETs 7g to 7n. Thus, the number of transistors included in the amplifier 6 in the final stage is larger than the number of transistors included in the amplifier 4 in the first stage.

Because the FETs in the amplifiers 4 to 6 are connected in a tournament fashion, the circuit is denser at the second stage than at the first stage and denser at the final stage than at the second stage. A combining circuit for combining outputs from the plurality of FETs of the amplifier 6 in the final stage and a multiplicity of pads are also disposed at the output side of the final stage. In a case where an MMIC of a three-stage configuration is formed on a conventional rectangular semiconductor substrate, empty spaces are left on the periphery of the second stage and larger empty spaces are left on the periphery of the first stage, because the size of the semiconductor substrate is selected according to the width of the final stage.

In the present embodiment, therefore, the semiconductor substrate 1 having a pentagonal contour is used, the amplifier 4 in the first stage is formed relatively near one vertex 2a, and the amplifier 6 in the final stage is formed relatively near the side 3a opposed to the vertex 2a. Empty spaces on the front stage side can thereby be reduced in comparison with the case of the conventional rectangular semiconductor substrate. The chip area can thus be reduced to reduce the chip cost.

FIG. 2 is a plan view showing a state where pentagonal semiconductor substrates are arranged on a wafer. The semiconductor substrates 1 are alternately arranged as illustrated and can thus be laid on the wafer with no margin. It is necessary, for realization of this arrangement, that the pentagonal shape of each semiconductor substrate 1 be a combination of an isosceles triangle including the vertex 2a and a rectangle including the side 3a.

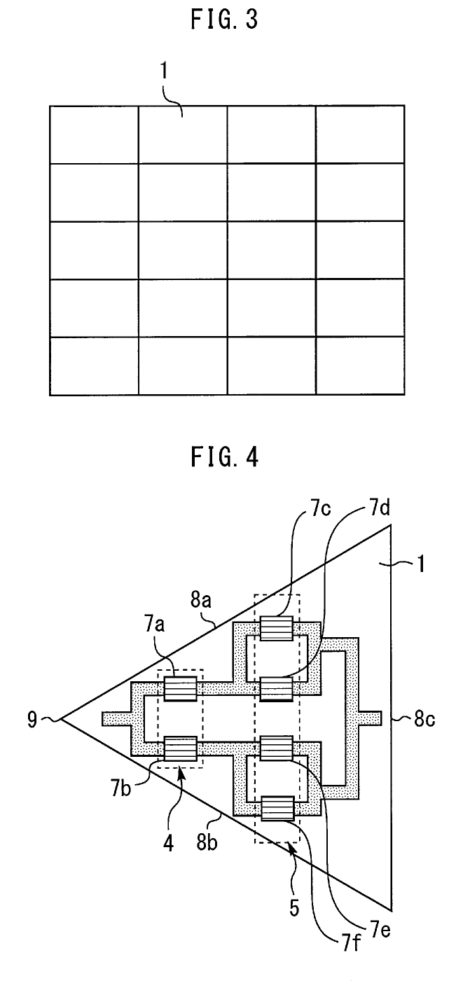

FIG. 3 is a plan view showing a state where conventional rectangular semiconductor substrates are arranged on a wafer. The number of chips per wafer is increased in the present embodiment in comparison with the case of the conventional rectangular semiconductor substrates, thus reducing the manufacturing cost per unit MMIC.

### Second Embodiment

FIG. 4 is a plan view showing a semiconductor device according to a second embodiment of the present invention. In the second embodiment, the contour of the semiconductor substrate 1 is an isosceles triangle having two first and second equal sides 8a and 8b equal in length to each other, and a bottom side 8c. The front-stage amplifier 4 is formed relatively near a vertex 9 shared by the first and second equal sides 8a and 8b of the semiconductor substrate 1, while the rear-stage amplifier 5 is formed relatively near the bottom side 8c of the semiconductor substrate 1. Empty spaces on the front stage side can thereby be reduced in comparison with the case of the conventional rectangular semiconductor substrate. The chip area can thus be reduced to reduce the chip cost.

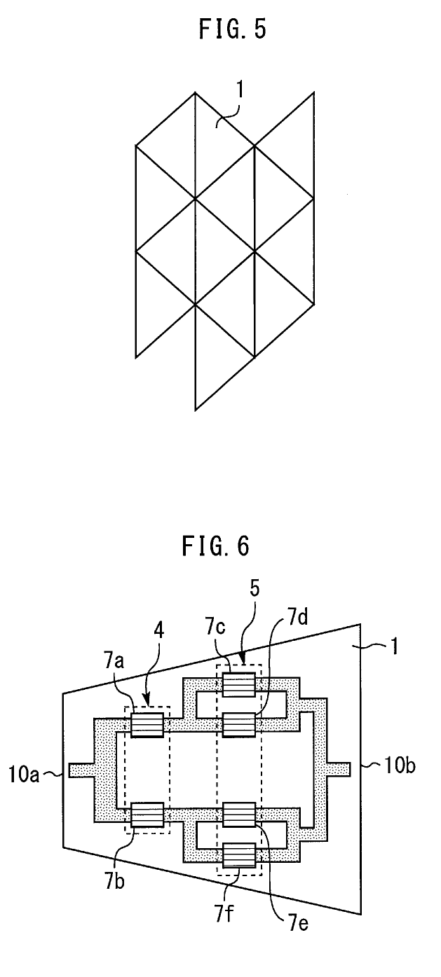

FIG. 5 is a plan view showing a state where semiconductor substrates in isosceles triangle form are arranged on a wafer. The semiconductor substrates 1 are alternately arranged as illustrated and can thus be laid on the wafer with no margin. The number of chips per wafer is increased in comparison with the case of the conventional rectangular semiconductor substrates, thus reducing the manufacturing cost per unit MMIC.

### Third Embodiment

FIG. 6 is a plan view showing a semiconductor device according to a third embodiment of the present invention. In the third embodiment, the contour of the semiconductor substrate 1 is an isosceles trapezoid having an upper base 10a and a lower base 10b parallel to the upper base 10a and longer than the upper base 10a. The front-stage amplifier 4 is formed relatively near the upper base 10a of the semiconductor substrate 1, while the rear-stage amplifier 5 is formed relatively near the lower base 10b of the semiconductor substrate 1. Empty spaces on the front stage side can thereby be reduced in comparison with the case of the conventional rectangular semiconductor substrate. The chip area can thus be reduced to reduce the chip cost.

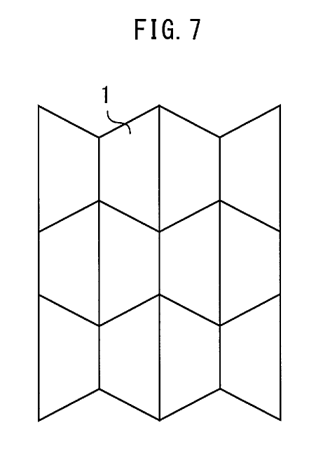

FIG. 7 is a plan view showing a state where semiconductor substrates in isosceles trapezoid form are arranged on a wafer. The semiconductor substrates 1 are alternately arranged as illustrated and can thus be laid on the wafer with no margin. The number of chips per wafer is increased in comparison with the case of the conventional rectangular semiconductor substrates, thus reducing the manufacturing cost per unit MMIC.

Obviously many modifications and variations of the present invention are possible in the light of the above teachings. It is therefore to be understood that within the scope of the appended claims the invention may be practiced otherwise than as specifically described.

The entire disclosure of Japanese Patent Application No. 2016-077526, filed on Apr. 7, 2016 including specification, claims, drawings and summary, on which the Convention priority of the present application is based, is incorporated herein by reference in its entirety.

1. A semiconductor device comprising:
a semiconductor substrate whose contour is a pentagon;
a front-stage amplifier formed relatively near a vertex of the pentagon of the semiconductor substrate; and
a rear-stage amplifier formed relatively near a side opposed to the vertex of the semiconductor substrate and amplifying an output from the front-stage amplifier.

2. The semiconductor device according to claim 1, wherein the pentagonal is a combination of an isosceles triangle including the vertex and a rectangle including the side.

3. The semiconductor device according to claim 1, wherein the number of transistors included in the rear-stage amplifier is larger than the number of transistors included in the front-stage amplifier.

4. A semiconductor device comprising:
a semiconductor substrate whose contour is an isosceles triangle having first and second equal sides equal in length to each other, and a bottom side;
a front-stage amplifier formed relatively near a vertex shared by the first and second equal sides of the semiconductor substrate; and
a rear-stage amplifier formed relatively near the bottom side of the semiconductor substrate and amplifying an output from the front-stage amplifier.

5. The semiconductor device according to claim 4, wherein the number of transistors included in the rear-stage amplifier is larger than the number of transistors included in the front-stage amplifier.

6. A semiconductor device comprising:
a semiconductor substrate whose contour is an isosceles trapezoid having an upper base and a lower base parallel to the upper base and longer than the upper base;
a front-stage amplifier formed relatively near the upper base of the semiconductor substrate; and
a rear-stage amplifier formed relatively near the lower base of the semiconductor substrate and amplifying an output from the front-stage amplifier.

7. The semiconductor device according to claim 6, wherein the number of transistors included in the rear-stage amplifier is larger than the number of transistors included in the front-stage amplifier.
